(19) United States
(12) Patent Application Publication
(10) Pub. No.: US 2023/0260929 A1
(43) Pub. Date: Aug. 17, 2023

(54) ELECTRONIC COMPONENT MODULE

(71) Applicant: Murata Manufacturing Co., Ltd., Nagaokakyo-shi, Kyoto-fu (JP)

(72) Inventors: Yoshihito OTSUBO, Nagaokakyo-shi (JP); Ryoichi KITA, Nagaokakyo-shi (JP); Tsuyoshi TAKAKURA, Nagaokakyo-shi (JP)

(21) Appl. No.: 18/301,322

(22) Filed: Apr. 17, 2023

Related U.S. Application Data
(63) Continuation of application No. PCT/JP2021/041035, filed on Nov. 8, 2021.

(30) Foreign Application Priority Data
Nov. 12, 2020 (JP) 2020-188586

(51) Int. Cl. H01L 23/552; H01L 25/16

(52) U.S. Cl. CPC H01L 23/552; H01L 25/16

(57) ABSTRACT

An electronic component module includes a substrate, a plurality of electronic components, an insulating sealing resin, a conductive film, and a conductive chip component. The plurality of electronic components includes an electronic component having a grounding terminal at a side end portion, and are mounted on the main surface of the substrate. The sealing resin covers the plurality of electronic components and the main surface side of the substrate. The conductive film covers the outer surface of the sealing resin. The conductive chip component is disposed on a side of the electronic component opposite to the substrate in a normal direction of the main surface, and is connected to a grounding terminal of the electronic component. The conductive film is connected to the conductive chip component.

### CROSS REFERENCE TO RELATED APPLICATION

This is a continuation of International Application No. PCT/JP2021/041035 filed on Nov. 8, 2021 which claims priority from Japanese Patent Application No. 2020-188586 filed on Nov. 12, 2020. The contents of these applications are incorporated herein by reference in their entireties.

### BACKGROUND OF THE DISCLOSURE

### Field of the Disclosure

The present disclosure relates to an electronic component module including a plurality of electronic components mounted on a substrate and having an electromagnetic shield structure.

### Description of the Related Art

Patent Literature 1 describes an electronic component module. The electronic component module described in Patent Literature 1 includes a circuit board, a surface mounted component, a sealing resin layer, and a shield layer.

The surface mount component is mounted on the circuit board. The sealing resin layer covers the mounting surface of the surface mount component in the circuit board. The shield layer covers an outer surface of the sealing resin layer.

In the sealing resin layer, a conductive post is formed so as to overlap the surface mount component in plan view. The conductive post is formed at a predetermined height and connects the surface mount component and the shield layer.

### Patent Literature 1

Japanese Patent No. 5321592

### BRIEF SUMMARY OF THE DISCLOSURE

However, in the configuration of Patent Literature 1, since the conductive post is used, there is a limit to improvement of conductivity, and there is a limit to the shielding property on both sides interposing the conductive post. In addition, since the conductive post is used, it can be formed only on the terminal of the surface mounting component, and it is difficult to enlarge the surface orthogonal to the mounting surface to function as a shield surface.

Therefore, a possible benefit of the present disclosure is to provide a high frequency module that can facilitate high-density mounting and suppress deterioration in shielding properties.

An electronic component module of the present disclosure includes a substrate having a main surface, a plurality of electronic components, an insulating sealing resin, a conductive film, and a conductive chip component. The plurality of electronic components includes a first electronic component including a grounding terminal at a side end portion, and is mounted on a main surface of the substrate. The insulating sealing resin covers the plurality of electronic components and the main surface side of the substrate. The conductive film covers the outer surface of the sealing resin. The conductive chip component is disposed on a side opposite to the substrate in the first electronic component in the normal direction of the main surface, and is connected to a grounding terminal of the first electronic component. The sealing resin has a concave portion for exposing the conductive chip component. The conductive film is formed in the concave portion and is connected to the conductive chip component. The sealing resin includes a concave portion in a portion overlapping the conductive chip component as viewed in a normal direction of the main surface. The conductive film has a portion formed in the concave portion. The conductive chip component is disposed between a portion formed along the concave portion and the first electronic component. A portion of the conductive film formed along the concave portion is connected to the conductive chip component.

In this configuration, the conductive chip component is connected to the ground potential, and electromagnetic field shielding properties can be realized. In addition, since the conductive chip component is used, the resistance value can be lowered, and the shielding property is hardly lowered. In addition, since the conductive chip component is disposed on the electronic component, it is not necessary to provide a region where the conductive chip component is disposed separately from the mounting region of the electronic component, and it is possible to secure a large number of mounting regions of the electronic component.

In addition, by disposing the conductive chip component on the electronic component, the distance to the conductive film on the top surface of the sealing resin becomes short, and the concave portion becomes shallow. Therefore, thinning of the conductive film formed in the concave portion is suppressed.

According to the present disclosure, it is possible to facilitate high-density mounting and to suppress deterioration in shielding properties.

### BRIEF DESCRIPTION OF THE SEVERAL VIEWS OF THE DRAWINGS

FIG. 1 is a plan perspective view of an electronic component module according to a first embodiment.

FIG. 2 is a side cross-sectional view of the electronic component module according to the first embodiment.

FIG. 3 is an enlarged side cross-sectional view of a part of the electronic component module according to the first embodiment.

FIG. 4 is an enlarged side cross-sectional view of a part of the electronic component module according to a second embodiment.

FIG. 5A is a side cross-sectional view of an electronic component module according to a third embodiment, and FIG. 5B is an enlarged side cross-sectional view of a part of the electronic component module according to the third embodiment.

FIG. 6 is a plan perspective view of an electronic component module according to a fourth embodiment.

FIG. 7 is a plan perspective view of an electronic component module according to a fifth embodiment.

FIG. 8 is an enlarged side cross-sectional view of a part of the electronic component module according to the fifth embodiment.

FIG. 9 is an enlarged side cross-sectional view of a part of an electronic component module according to a sixth embodiment.

FIG. 10 is an enlarged side cross-sectional view of a part of an electronic component module according to a seventh embodiment.

FIG. 11 is a plan perspective view of an electronic component module according to an eighth embodiment.

FIG. 12 is an enlarged side cross-sectional view of a part of the electronic component module according to the eighth embodiment.

FIG. 13 is a plan perspective view of an electronic component module according to a ninth embodiment.

FIG. 14 is an enlarged side cross-sectional view of a part of the electronic component module according to the ninth embodiment.

FIG. 15 is a plan perspective view of an electronic component module according to a tenth embodiment.

### DETAILED DESCRIPTION OF THE DISCLOSURE

### First embodiment

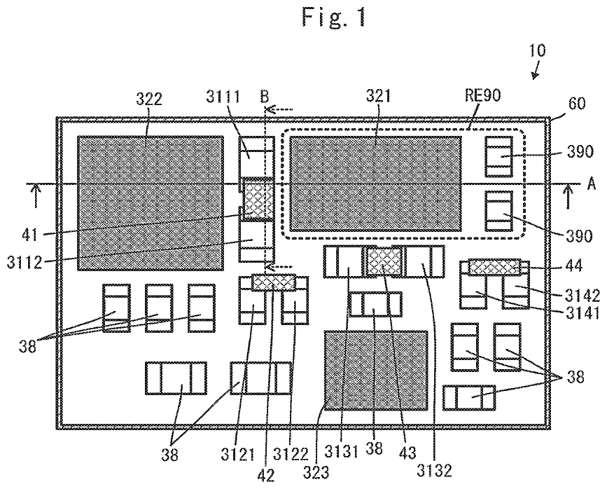

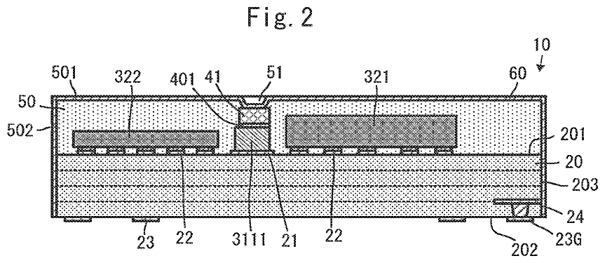

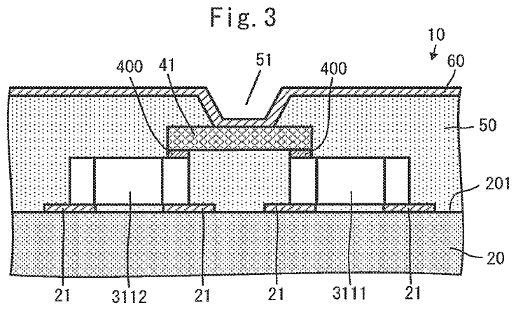

An electronic component module according to a first embodiment of the present disclosure will be described with reference to the drawings. FIG. 1 is a plan perspective view of an electronic component module according to the first embodiment. Note that FIG. 1 is a plan perspective view in a state where a top surface portion of a sealing resin and a shield film is seen through. FIG. 2 is a side cross-sectional view of the electronic component module according to the first embodiment. FIG. 3 is an enlarged side cross-sectional view of a part of the electronic component module according to the first embodiment. FIG. 2 illustrates a cross section A of FIG. 1, and FIG. 3 illustrates a cross section B of FIG. 1. FIGS. 2 and 3 are not strict cross-sectional views, but are cross-sectional views in which the characteristic configuration of the disclosure is made to be easily understood. In the following plurality of embodiments, the plan view and the side cross-sectional view are described for the same purpose as in the first embodiment.

In FIGS. 1, 2, and 3, dimensions are emphasized as appropriate for easy understanding of the configuration. Note that such illustration is performed not only in the first embodiment but also in other embodiments.

An electronic component module 10 is used, for example, as a front-end module for a high-frequency communication signal.

As illustrated in FIGS. 1, 2, and 3, the electronic component module 10 includes a substrate 20, an electronic component 3111, an electronic component 3112, an electronic component 3121, an electronic component 3122, an electronic component 3131, an electronic component 3132, an electronic component 3141, an electronic component 3142, an electronic component 321, an electronic component 322, an electronic component 323, a plurality of electronic components 38, a plurality of electronic components 390, a conductive chip component 41, a conductive chip component 42, a conductive chip component 43, a conductive chip component 44, a sealing resin 50, and a conductive film 60.

The substrate 20 has an insulating main body and includes a conductor pattern for realizing the electronic component module 10. The substrate 20 is, for example, configured such that a plurality of insulator layers having a predetermined conductor pattern are stacked. As illustrated in FIG. 2, for example, the conductor pattern includes a grounding conductor pattern 24 and an interlayer connection conductor connected to the conductor pattern 24.

The substrate 20 is, for example, a rectangular flat plate, and has a main surface 201 and a main surface 202 facing each other. The substrate 20 is formed of a ceramic multilayer substrate or a resin multilayer substrate.

A plurality of land electrodes for mounting electronic components are formed on the main surface 201 of the substrate 20. The plurality of land electrodes include a land electrode 21 for an electronic component including a grounding terminal at a side end portion of the main body, and a land electrode 22 for an electronic component including a grounding terminal at a bottom surface of the main body.

A terminal electrode 23 for external connection is formed on the main surface 202 of the substrate 20. A predetermined number of terminal electrodes 23 for external connection are formed according to the specifications of the electronic component module 10.

The electronic component 3111, the electronic component 3112, the electronic component 3121, the electronic component 3122, the electronic component 3131, the electronic component 3132, the electronic component 3141, the electronic component 3142, the plurality of electronic components 38, and the plurality of electronic components 390 are electronic components each including a grounding terminal at a side end portion of a main body. The grounding terminal also has a shape extending to the top surface and the bottom surface of the electronic component. However, the component on which the conductive chip component is not mounted may be an LGA type component.

These electronic components are, for example, chip inductors, chip multilayer capacitors, chip resistors, LC filter elements, balun elements, coupler elements, matching device elements, and the like. These electronic components may be elements of an antenna switch matching circuit, a PA matching circuit, and an LNA matching circuit. These electronic components are connected to the land electrode 21 by a conductive bonding material such as solder.

The electronic component 321, the electronic component 322, and the electronic component 323 are electronic components including a grounding terminal on a bottom surface of a main body. The main body is molded with, for example, an insulating resin. These electronic components are LNAs, semiconductor ICs that form switch circuits, and the like. These electronic components are connected to the land electrode 22 by a conductive bonding material such as solder.

The electronic component 321, the electronic component 322, the electronic component 323, and the plurality of electronic components 38 are disposed at predetermined positions according to the circuit configuration realized by the electronic component module 10.

When viewed in the normal direction of the main surface 201, the electronic component 3111 and the electronic component 3112 are disposed between the electronic component 321 and the electronic component 322. The electronic component 3111 and the electronic component 3112 are disposed substantially parallel to the side surfaces of the electronic component 321 and the electronic component 322 facing each other. The electronic component 3111 and the electronic component 3112 are adjacent to each other. The grounding terminal of the electronic component 3111 and the grounding terminal of the electronic component 3112 face each other closely.

When viewed in the normal direction of main surface 201, the electronic component 3121 and the electronic component 3122 are disposed between the electronic component 321 and the electronic component 322, and the predetermined electronic component 38. The electronic component 3121 and the electronic component 3122 are disposed, for example, substantially parallel to predetermined side surfaces of the electronic component 321 and the electronic component 322. The electronic component 3121 and the electronic component 3122 are adjacent to each other. The grounding terminal of the electronic component 3121 and the grounding terminal of the electronic component 3122 are adjacent to each other in a direction in which these electronic components are arranged.

When viewed in the normal direction of the main surface 201, the electronic component 3131 and the electronic component 3132 are disposed between the electronic component 321 and the electronic component 323 and the predetermined electronic component 38. The electronic component 3131 and the electronic component 3132 are disposed, for example, substantially parallel to a predetermined side surface of the electronic component 321. The electronic component 3131 and the electronic component 3132 are adjacent to each other. The grounding terminal of the electronic component 3131 and the grounding terminal of the electronic component 3132 face each other closely.

When viewed in the normal direction of main surface 201, the electronic component 3141 and the electronic component 3142 are disposed between the electronic component 321 and the predetermined electronic component 38. The electronic component 3141 and the electronic component 3142 are disposed, for example, substantially in parallel on a predetermined side surface of the electronic component 321. The electronic component 3141 and the electronic component 3142 are adjacent to each other. The grounding terminal of the electronic component 3141 and the grounding terminal of the electronic component 3142 are adjacent to each other in a direction in which these electronic components are arranged.

The plurality of electronic components 390 is disposed close to the electronic component 321.

The conductive chip component 41, the conductive chip component 42, the conductive chip component 43, and the conductive chip component 44 are rectangular parallelepiped metal. That is, the plurality of conductive chip components 41 to 44 are not made of a conductor such as a conductive post containing a resin filler or the like, but is made of a material having a higher conductivity than the conductive post, such as a pure metal body (for example, a metal body having a higher conductivity of aluminum or copper).

The conductive chip component 41 is disposed on the electronic component 3111 and the electronic component 3112 on a side opposite to the substrate 20 in the normal direction of the main surface 201. When viewed in the normal direction of the main surface 201, the conductive chip component 41 overlaps the grounding terminal of the electronic component 3111 and the grounding terminal of the electronic component 3112. The conductive chip component 41 is connected and fixed to the grounding terminal of the electronic component 3111 and the grounding terminal of the electronic component 3112 by a conductive adhesive 400. In this case, the electronic component 3111 and the electronic component 3112 correspond to the “first electronic component” and the “second electronic component” of the present disclosure.

The conductive chip component 42 is disposed on the electronic component 3121 and the electronic component 3122 on a side opposite to the substrate 20 in the normal direction of the main surface 201. When viewed in the normal direction of the main surface 201, the conductive chip component 42 overlaps the grounding terminal of the electronic component 3121 and the grounding terminal of the electronic component 3122. The conductive chip component 42 is connected and fixed to the grounding terminal of the electronic component 3121 and the grounding terminal of the electronic component 3122 by a conductive adhesive. Instead of the conductive adhesive, for example, solder may be used. In this case, the electronic component 3121 and the electronic component 3122 correspond to the “first electronic component” and the “second electronic component” of the present disclosure.

The conductive chip component 43 is disposed on the electronic component 3131 and the electronic component 3132 on a side opposite to the substrate 20 in the normal direction of the main surface 201. When viewed in the normal direction of the main surface 201, the conductive chip component 43 overlaps the grounding terminal of the electronic component 3131 and the grounding terminal of the electronic component 3132. The conductive chip component 43 is connected and fixed to the grounding terminal of the electronic component 3131 and the grounding terminal of the electronic component 3132 by a conductive adhesive. In this case, the electronic component 3131 and the electronic component 3132 correspond to the “first electronic component” and the “second electronic component” of the present disclosure.

The conductive chip component 44 is disposed on the electronic component 3141 and the electronic component 3142 on a side opposite to the substrate 20 in the normal direction of the main surface 201. When viewed in the normal direction of the main surface 201, the conductive chip component 44 overlaps the grounding terminal of the electronic component 3141 and the grounding terminal of the electronic component 3142. The conductive chip component 44 is connected and fixed to the grounding terminal of the electronic component 3141 and the grounding terminal of the electronic component 3142 by a conductive adhesive. In this case, the electronic component 3141 and the electronic component 3142 correspond to the “first electronic component” and the “second electronic component” of the present disclosure.

The sealing resin 50 covers the main surface 201 side of the substrate 20. The sealing resin 50 covers the plurality of electronic components and the plurality of conductive chip components mounted on the main surface 201 side. The sealing resin 50 is made of an insulating resin.

The sealing resin 50 has a concave portion 51. The concave portion 51 has a shape recessed from a top surface 501 of the sealing resin 50. When viewed in the normal direction of the main surface 201, the concave portion 51 is formed at a position overlapping the conductive chip component 41, a position overlapping the conductive chip component 42, a position overlapping the conductive chip component 43, and a position overlapping the conductive chip component 44.

The conductive film 60 covers the outer surface (the top surface 501 and the side surface 502) of the sealing resin 50 and the side surface 203 of the substrate 20. The conductive film 60 is connected to the grounding conductor pattern 24 of the substrate 20.

The conductive film 60 is also formed on the wall surfaces of the plurality of concave portions 51. With the concave portion 51 reaching the conductive chip components 41, 42, and 43, the conductive film 60 is connected (conducted) to the conductive chip component 41, the conductive chip component 42, the conductive chip component 43, and the conductive chip component 44.

The conductive film 60 is, for example, a metal film formed by sputtering, plating, or the like. The conductive film 60 has, for example, a configuration in which an adhesion layer, a conductive layer, and an antiseptic layer are stacked. The adhesion layer is made of, for example, stainless steel (SUS). The conductive layer is made of, for example, copper (Cu), silver (Ag), aluminum (Al), or the like. A rust prevention layer is made of, for example, stainless steel (SUS).

With such a configuration, the plurality of conductive chip components 41 to 44 are connected to the ground potential.

Therefore, electromagnetic field coupling between the electronic component 321 and the electronic component 322 disposed with the conductive chip component 41 interposed therebetween is suppressed by the conductive chip component 41. As a result, electromagnetic field shielding properties between the electronic component 321 and the electronic component 322 are improved.

By the conductive chip component 42, the electromagnetic field coupling between the electronic component 321 and the electronic component 322 disposed with the conductive chip component 42 interposed therebetween and the predetermined electronic component 38 is suppressed. As a result, the electromagnetic field shielding properties between the electronic component 321 and the electronic component 322 disposed with the conductive chip component 42 interposed therebetween and the predetermined electronic component 38 are improved. Alternatively, when the electronic component 38 is an inductor, it is possible to improve a shielding property against a magnetic field generated by the inductor. Since the cause of the isolation deterioration is particularly caused by the magnetic flux coupling of an inductor of the matching circuit, it is particularly necessary to strengthen the compartment shield around the matching circuit.

The electromagnetic field coupling between the electronic component 321 disposed with the conductive chip component 43 interposed and the predetermined electronic component 38 and electronic component 323 is suppressed by the conductive chip component 43. As a result, the electromagnetic field shielding properties between the electronic component 321 disposed with the conductive chip component 43 interposed and the predetermined electronic component 38 and electronic component 323 are improved. Alternatively, when the electronic component 38 is an inductor, it is possible to improve a shielding property against a magnetic field generated by the inductor.

The conductive chip component 44 suppresses electromagnetic field coupling with the electronic component 321 and the predetermined electronic component 38 disposed with the conductive chip component 44 interposed therebetween. As a result, electromagnetic field shielding properties between the electronic component 321 and the predetermined electronic component 38 disposed with the conductive chip component 44 interposed therebetween are improved. Alternatively, when the electronic component 390 and the electronic component 38 are any of an antenna switch matching circuit, a PA matching circuit, and an LNA matching circuit element, the shielding property for the matching circuit element can be improved.

In addition, in this configuration, the conductive chip components 41, 42, 43, and 44 have low resistance values. The conductive chip components 41, 42, 43, and 44 have higher conductivity than, for example, a conductive post containing a resin filler or the like. Therefore, each electromagnetic field shielding property is further improved. Further, in plan view, the conductive chip components 41, 42, 43, and 44 can be larger than the grounding terminals of the electronic components. As a result, the electromagnetic shielding property is further improved.

In addition, in this configuration, the conductive chip components 41, 42, 43, and 44 are disposed on a side opposite to the substrate 20 in the electronic component to which they are connected. As a result, in the normal direction of the main surface 201, the distance between the conductive chip components 41, 42, 43, and 44 and the conductive film 60 formed on the top surface 501 of the sealing resin 50 is shorter than that in the configuration in which the conductive chip components 41, 42, 43, and 44 are directly mounted on the main surface 201 of the substrate 20. Therefore, the concave portion 51 can be made shallow, and the conductive film 60 formed in the concave portion 51 can be suppressed from becoming thin. As a result, electromagnetic field shielding properties are further improved.

Further, in this configuration, a region for mounting the conductive chip components 41, 42, 43, and 44 may not be provided on the main surface 201. As a result, the electronic component module 10 can realize high density of electronic components.

Further, in this configuration, for example, the electronic component module 10 realizes a high frequency module, the electronic component 321 constitutes an LNA (amplifying element of a reception system of a high frequency signal), and the plurality of electronic components 390 constitutes a matching circuit for the LNA. Then, the electronic component 321 and the plurality of electronic components 390 constitute a specific functional circuit RE 90 including the LNA and its matching circuit. In this case, the plurality of conductive chip components 41, 42, 43, 44 are disposed so as to surround this specific functional circuit. As a result, electromagnetic field coupling between this specific functional circuit and other circuits can be effectively suppressed. In other words, the shielding property for a specific functional circuit can be improved. For example, it is possible to improve the shielding property of noise generated by other switching circuits and the like with respect to a circuit that is easily affected by noise including an LNA.

In this configuration, when the plurality of electronic components is disposed such that the grounding terminal is arranged in parallel to the side surface of the electronic component 321 (see, for example, the electronic component 3121 and the electronic component 3122.), the grounding terminal is disposed on the electronic component 321 side. Then, a conductive chip component is disposed on these grounding terminals (see, e.g., the conductive chip component 42). As a result, when viewed in the normal direction of the main surface 201, no other electronic components exist between the conductive chip component and the electronic component whose shielding property is desired to be improved. As a result, the shielding property of the electronic component whose shielding property is desired to be improved can be further improved.

### (Method of Manufacturing Electronic Component Module According to First Embodiment)

The electronic component module 10 having the above-described configuration is manufactured, for example, as follows.

A plurality of electronic components is mounted on the substrate 20.

A plurality of conductive chip components is connected and fixed to the top surface (the surface opposite to the substrate 20) of a predetermined electronic component.

An insulating resin is applied to the main surface 201 side of the substrate 20 and cured to form the sealing resin 50. The sealing resin 50 is ground to a predetermined thickness.

The sealing resin 50 is ground from the top surface 501 side to form the concave portion 51 that exposes the top surfaces of the plurality of conductive chip components.

The conductive film 60 is formed on the sealing resin 50 including the concave portion 51.

By using such a manufacturing method, the electronic component module 10 having excellent electromagnetic shielding properties and increased in density can be easily and more reliably formed.

### Second Embodiment

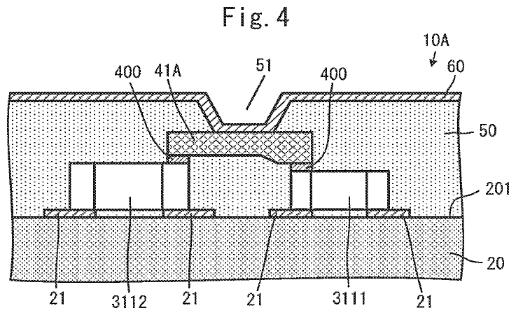

An electronic component module according to a second embodiment of the present disclosure will be described with reference to the drawings. FIG. 4 is an enlarged side cross-sectional view of a part of the electronic component module according to the second embodiment.

As illustrated in FIG. 4, an electronic component module 10A according to the second embodiment is different from the electronic component module 10 according to the first embodiment in that a conductive chip component 41A is provided. Other configurations of the electronic component module 10A are similar to those of the electronic component module 10, and description of the similar parts will be omitted.

In the electronic component module 10A, the electronic component 3111 is lower in height than the electronic component 3112.

The conductive chip component 41A has a first portion overlapping the electronic component 3111 and a second portion overlapping the electronic component 3112 when viewed in the normal direction of the main surface 201. The first portion is thicker than the second portion.

The conductive chip component 41A has a step due to a difference in thickness between the first portion and the second portion. The conductive chip component 41A is disposed such that the surface having the step is on the electronic component 3111 side and the electronic component 3112 side.

The first portion of the conductive chip component 41A is connected and fixed to the grounding terminal of the electronic component 3111 by the conductive adhesive 400. The second portion of the conductive chip component 41A is connected and fixed to the grounding terminal of the electronic component 3112 by the conductive adhesive 400.

With this configuration, even if the electronic component 3111 and the electronic component 3112 have different heights, the conductive chip component 41A can be easily and more reliably installed.

In such a configuration, similarly to the electronic component module 10, the electronic component module 10A can realize high density mounting and high shielding properties.

### Third Embodiment

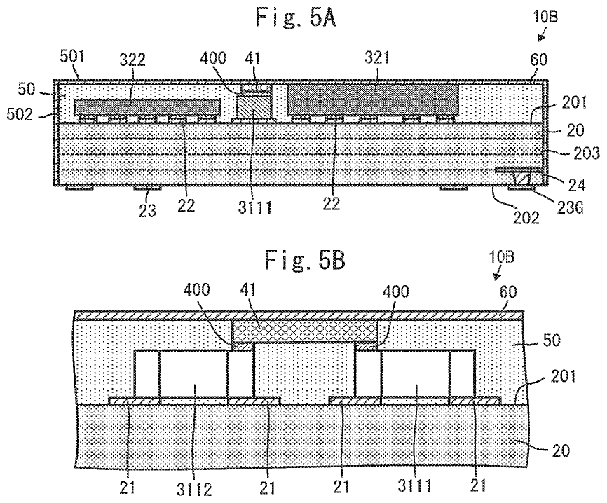

An electronic component module according to a third embodiment of the present disclosure will be described with reference to the drawings. FIG. 5A is a side cross-sectional view of an electronic component module according to the third embodiment, and FIG. 5B is an enlarged side cross-sectional view of a part of the electronic component module according to the third embodiment.

As illustrated in FIGS. 5(A) and 5(B), an electronic component module 10B according to the third embodiment is different from the electronic component module 10 according to the first embodiment in that the electronic component module does not have the concave portion 51. Other configurations of the electronic component module 10B are similar to those of the electronic component module 10, and description of the similar parts will be omitted.

In the electronic component module 10B, as in the first embodiment, the conductive chip component 41 is disposed so as to overlap the grounding terminal of the electronic component 3111 and the grounding terminal of the electronic component 3112, and is connected and fixed to each grounding terminal by the conductive adhesive 400. The top surface of the conductive chip component 41 and the top surface of the electronic component 321 are flush with each other. In other words, in the height direction of the electronic component module 10B, the position of the top surface of the conductive chip component 41 and the position of the top surface of the electronic component 321 are the same.

Further, the top surface 501 of the sealing resin 50 is flush with the top surface of the conductive chip component 41 and the top surface of the electronic component 321.

With such a configuration, the conductive film 60 is formed flat with respect to the top surface 501 of the sealing resin 50, the top surface of the conductive chip component 41, and the top surface of the electronic component 321. In such a configuration, similarly to the electronic component module 10, the electronic component module 10B can realize high density mounting and high shielding property. Further, in the electronic component module 10B, the height of the module can be further reduced. In addition, since the concave portion 51 is eliminated, the thickness of the conductive film 60 can be more reliably made uniform. As a result, the electronic component module 10B can realize the shielding property more reliably.

### Fourth Embodiment

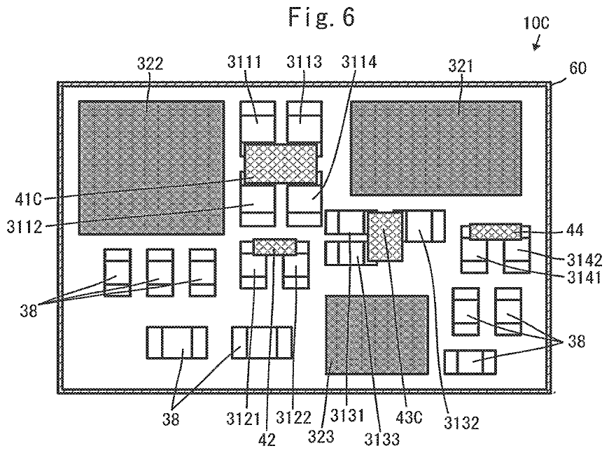

An electronic component module according to a fourth embodiment of the present disclosure will be described with reference to the drawings. FIG. 6 is a plan perspective view of an electronic component module according to the fourth embodiment. Note that FIG. 6 is a plan perspective view in a state where a top surface portion of the sealing resin and the shield film is seen through.

As illustrated in FIG. 6, an electronic component module 10C according to the fourth embodiment is different from the electronic component module 10 according to the first embodiment in terms of an arrangement mode of a conductive chip component 41C and a conductive chip component 43C. Other configurations of the electronic component module 10C are similar to those of the electronic component module 10, and description of the similar parts will be omitted.

The electronic component 3111, the electronic component 3112, the electronic component 3113, and the electronic component 3114 are disposed between the electronic component 321 and the electronic component 322. The electronic component 3111, the electronic component 3112, the electronic component 3113, and the electronic component 3114 are disposed adjacent to each other.

The conductive chip component 41C is disposed so as to overlap the respective grounding terminals of the electronic component 3111, the electronic component 3112, the electronic component 3113, and the electronic component 3114, and is connected and fixed to these grounding terminals.

The electronic component 3131, the electronic component 3132, and the electronic component 3133 are disposed between the electronic component 321 and the electronic component 323. The electronic component 3131, the electronic component 3132, and the electronic component 3133 are disposed adjacent to each other.

The conductive chip component 43C is disposed so as to overlap the respective grounding terminals of the electronic component 3131, the electronic component 3132, and the electronic component 3133, and is connected and fixed to these grounding terminals.

In such a configuration, similarly to the electronic component module 10, the electronic component module 10C can realize high-density mounting and high shielding properties. In this configuration, the planar shapes of the conductive chip component 41C and the conductive chip component 43C can be increased. This facilitates installation of the conductive chip component 41C and the conductive chip component 43C. In addition, the shielding property by the conductive the conductive chip component 41C and the conductive chip component 43C is improved.

### Fifth Embodiment

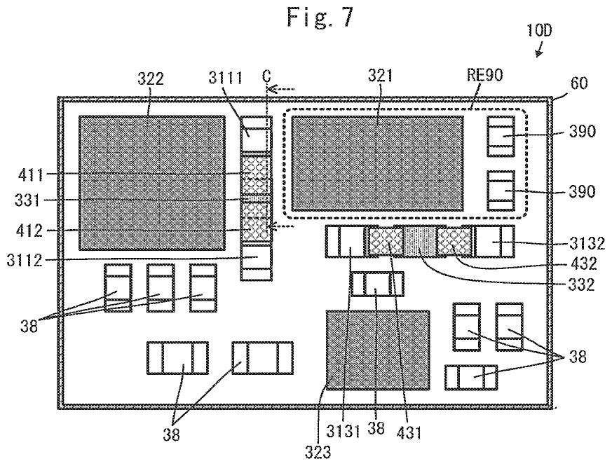

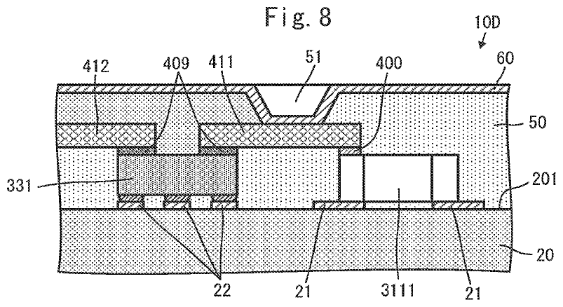

An electronic component module according to a fifth embodiment of the present disclosure will be described with reference to the drawings. FIG. 7 is a plan perspective view of an electronic component module according to the fifth embodiment. Note that FIG. 7 is a plan perspective view in a state where a top surface portion of the sealing resin and the shield film is seen through. FIG. 8 is an enlarged side cross-sectional view of a part of the electronic component module according to the fifth embodiment.

As illustrated in FIGS. 7 and 8, an electronic component module 10D according to the fifth embodiment is different from the electronic component module 10 according to the first embodiment in the type of electronic component in which a conductive chip component is disposed. Other specific configurations of the electronic component module 10D are similar to those of the electronic component module 10, and description of the similar parts will be omitted.

The electronic component module 10D includes an electronic component 3111, an electronic component 3112, an electronic component 3131, an electronic component 3132, an electronic component 331, and an electronic component 332. In addition, the electronic component module 10D includes a conductive chip component 411, a conductive chip component 412, a conductive chip component 431, and a conductive chip component 432.

The electronic component 3111, the electronic component 3112, the electronic component 3131, and the electronic component 3132 are electronic components each including a grounding terminal at a side end portion of a main body. The grounding terminal also has a shape extending to the top surface and the bottom surface of the electronic component.

The electronic component 331 and the electronic component 332 are electronic components including a grounding terminal on the bottom surface of the main body. The main body is molded with, for example, an insulating resin.

The electronic component 3111, the electronic component 331, and the electronic component 3112 are disposed in this order with a space therebetween. The electronic component 3111, the electronic component 331, and the electronic component 3112 are disposed between the electronic component 321 and the electronic component 322. The direction in which the electronic component 3111, the electronic component 331, and the electronic component 3112 are arranged is, for example, substantially parallel to the facing surfaces of the electronic component 321 and the electronic component 322.

The electronic component 3131, the electronic component 332, and the electronic component 3132 are disposed in this order with a space therebetween. The electronic component 3131, the electronic component 332, and the electronic component 3132 are disposed between the electronic component 321 and the electronic component 323. The direction in which the electronic component 3131, the electronic component 332, and the electronic component 3132 are arranged is, for example, substantially parallel to the facing surfaces of the electronic component 321 and the electronic component 323.

In the normal direction of the main surface 201, the conductive chip component 411 is disposed on a side opposite to the substrate 20 with respect to the electronic component 3111 and the electronic component 331. When viewed in the normal direction of the main surface 201, the conductive chip component 411 overlaps the electronic component 3111 and the electronic component 331. The conductive chip component 411 is connected and fixed to the grounding terminal of the electronic component 3111 by the conductive adhesive 400. The conductive chip component 411 is fixed to the top surface of the main body of the electronic component 331 with an adhesive 409. In this case, the electronic component 331 corresponds to a “fourth electronic component” of the present disclosure.

In the normal direction of the main surface 201, the conductive chip component 412 is disposed on a side opposite to the substrate 20 with respect to the electronic component 3112 and the electronic component 331. When viewed in the normal direction of the main surface 201, the conductive chip component 412 overlaps the electronic component 3112 and the electronic component 331. The conductive chip component 412 is connected and fixed to the grounding terminal of the electronic component 3112 by the conductive adhesive 400. The conductive chip component 412 is fixed to the top surface of the main body of the electronic component 331 with an adhesive 409.

In the normal direction of the main surface 201, the conductive chip component 431 is disposed on a side opposite to the substrate 20 with respect to the electronic component 3131 and the electronic component 332. When viewed in the normal direction of the main surface 201, the conductive chip component 431 overlaps the electronic component 3131 and the electronic component 332. The conductive chip component 431 is connected and fixed to the grounding terminal of the electronic component 3131 by the conductive adhesive 400. The conductive chip component 431 is fixed to the top surface of the main body of the electronic component 332 with the adhesive 409. In this case, the electronic component 332 corresponds to a “fourth electronic component” of the present disclosure.

In the normal direction of the main surface 201, the conductive chip component 432 is disposed on a side opposite to the substrate 20 with respect to the electronic component 3132 and the electronic component 332. When viewed in the normal direction of the main surface 201, the conductive chip component 432 overlaps the electronic component 3132 and the electronic component 332. The conductive chip component 432 is connected and fixed to the grounding terminal of the electronic component 3132 by the conductive adhesive 400. The conductive chip component 432 is fixed to the top surface of the main body of the electronic component 332 with the adhesive 409.

In such a configuration, similarly to the electronic component module 10, the electronic component module 10D can realize high-density mounting and high shielding properties.

The adhesive 409 is preferably insulating. As a result, the electronic component module 10D can prevent the electronic component 331 and the electronic component 332 from being undesirably short-circuited to the conductive chip component.

### Sixth Embodiment

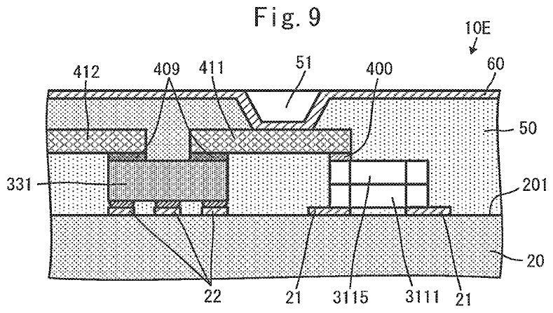

An electronic component module according to a sixth embodiment of the present disclosure will be described with reference to the drawings. FIG. 9 is an enlarged side cross-sectional view of a part of an electronic component module according to the sixth embodiment.

As illustrated in FIG. 9, an electronic component module 10E according to the sixth embodiment is different from the electronic component module 10D according to the fifth embodiment in that an electronic component 3111 and an electronic component 3115 are stacked. Other configurations of the electronic component module 10E are similar to those of the electronic component module 10D, and description of the similar parts will be omitted.

The electronic component module 10E includes an electronic component 3111 and an electronic component 3115. The electronic component 3111 and the electronic component 3115 are electronic components including a grounding terminal at a side end portion of a main body. The grounding terminal also has a shape extending to the top surface and the bottom surface of the electronic component. The electronic component 3111 and the electronic component 3115 are lower in height than the electronic component 331.

The electronic component 3111 and the electronic component 3115 are stacked. The electronic component 3111 and the electronic component 3115 overlap when viewed from the normal direction of the main surface 201. Further, the grounding terminal of the electronic component 3111 and the grounding terminal of the electronic component 3115 overlap each other when viewed from the normal direction of the main surface 201. Terminals of the electronic component 3111 and the electronic component 3115 are connected by a conductive bonding material such as solder.

The electronic component 3111 is mounted on the land electrode 21 of the substrate 20. The conductive chip component 411 is connected and fixed to the grounding terminal of the electronic component 3115 by a conductive adhesive 400.

In such a configuration, similarly to the electronic component module 10D, the electronic component module 10E can realize high-density mounting and high shielding properties. Further, in this configuration, by stacking a plurality of electronic components, higher density mounting can be realized.

### Seventh Embodiment

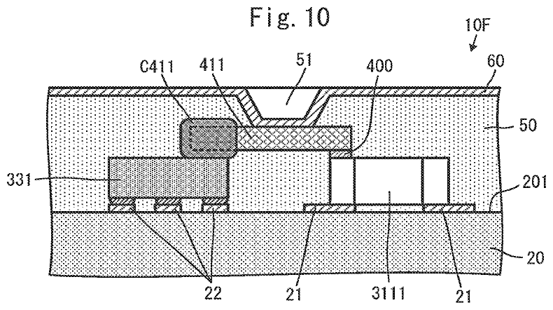

An electronic component module according to a seventh embodiment of the present disclosure will be described with reference to the drawings. FIG. 10 is an enlarged side cross-sectional view of a part of the electronic component module according to the seventh embodiment.

As illustrated in FIG. 10, an electronic component module 10F according to the seventh embodiment is different from the electronic component module 10D according to the fifth embodiment in terms of an arrangement mode of the conductive chip component 411 on the electronic component 331. Other configurations of the electronic component module 10F are similar to those of the electronic component module 10D, and description of the similar parts will be omitted.

A portion of the conductive chip component 411 overlapping the electronic component 331 is covered with an insulating film C411. The insulating film C411 abuts on the top surface of the electronic component 331.

In such a configuration, similarly to the electronic component module 10D, the electronic component module 10F can realize high-density mounting and high shielding properties. Further, in this configuration, since the portion of the conductive chip component 411 covered with the insulating film C411 abuts on the electronic component 331, an undesirable short circuit between the conductive chip component 411 and the electronic component 331 can be more reliably suppressed.

### Eighth Embodiment

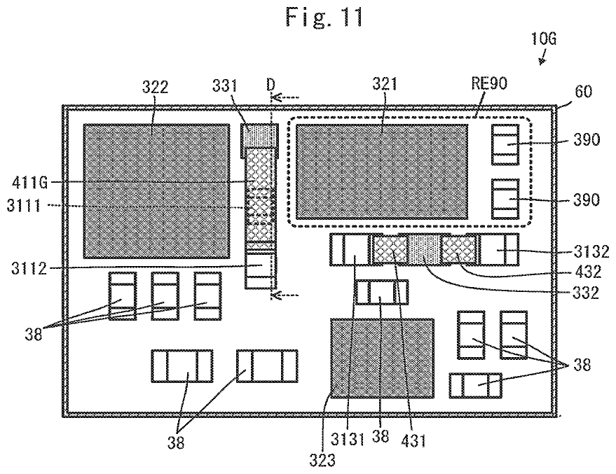

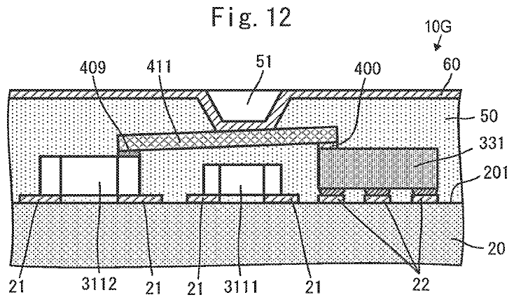

An electronic component module according to an eighth embodiment of the present disclosure will be described with reference to the drawings. FIG. 11 is a plan perspective view of an electronic component module according to the eighth embodiment. Note that FIG. 11 is a plan perspective view in a state where a top surface portion of the sealing resin and the shield film is seen through. FIG. 12 is an enlarged side cross-sectional view of a part of the electronic component module according to the eighth embodiment.

As illustrated in FIGS. 11 and 12, an electronic component module 10G according to the eighth embodiment is different from the electronic component module 10D according to the fifth embodiment in terms of an arrangement mode of a conductive chip component 411G. Other specific configurations of the electronic component module 10G are similar to those of the electronic component module 10D, and description of the similar parts will be omitted.

The electronic component module 10G includes an electronic component 331, an electronic component 3111, an electronic component 3112, and a conductive chip component 411G. The electronic component 331, the electronic component 3111, and the electronic component 3112 are disposed in this order.

When viewed in the normal direction of the main surface 201, the conductive chip component 411G overlaps the electronic component 331, the electronic component 3111, and the electronic component 3112. The conductive chip component 411G is connected and fixed to the grounding terminal of the electronic component 3112 by the conductive adhesive 400. The conductive chip component 411G is fixed to the top surface of the electronic component 331 by an adhesive 409. In the normal direction of the main surface 201, the conductive chip component 411G is spaced apart from the electronic component 3111. That is, the conductive chip component 411G jumps over the top surface side of the electronic component 3111, is fixed to the electronic component 331 and the electronic component 3112, and is connected to the grounding terminal of the electronic component 3112. In this case, the electronic component 331 corresponds to the “fourth electronic component” of the present disclosure, the electronic component 3112 corresponds to the “first electronic component” of the present disclosure, and the electronic component 3111 corresponds to the “fifth electronic component” of the present disclosure.

Note that the electronic component 331 can be replaced with an electronic component similar to the electronic component 3111 and the electronic component 3112. In this case, the replaced electronic component and the electronic component 3112 correspond to the “first electronic component” and the “second electronic component” of the present disclosure, and the electronic component 3111 corresponds to the “third electronic component” of the present disclosure.

In such a configuration, similarly to the electronic component module 10D, the electronic component module 10G can realize high-density mounting and high shielding properties. Further, in this configuration, the planar shape of the conductive chip component 411G can be increased. As a result, stability during mounting and after fixing of the conductive chip component 411G is improved.

### Ninth Embodiment

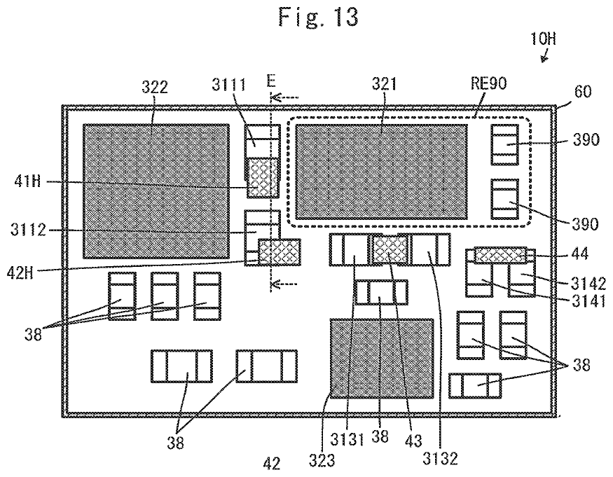

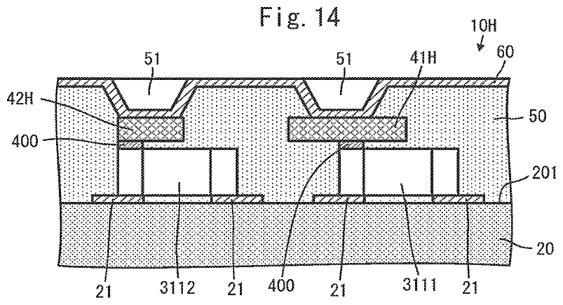

An electronic component module according to a ninth embodiment of the present disclosure will be described with reference to the drawings. FIG. 13 is a plan perspective view of an electronic component module according to the ninth embodiment. Note that FIG. 13 is a plan perspective view in a state where a top surface portion of the sealing resin and the shield film is seen through. FIG. 14 is an enlarged side cross-sectional view of a part of the electronic component module according to the ninth embodiment.

As illustrated in FIGS. 13 and 14, an electronic component module 10H according to the ninth embodiment is different from the electronic component module 10 according to the first embodiment in terms of an arrangement mode of a conductive chip component on an electronic component. Other specific configurations of the electronic component module 10H are similar to those of the electronic component module 10, and description of the similar parts will be omitted.

The electronic component module 10H includes a conductive chip component 41H and a conductive chip component 42H. The conductive chip component 41H overlaps the electronic component 3111 when viewed in the normal direction of the main surface 201. The conductive chip component 41H is connected and fixed to the grounding terminal of the electronic component 3111 by a conductive adhesive 400. The conductive chip component 41H is connected to the conductive film 60 formed in the concave portion 51 of the sealing resin 50. The conductive chip component 42H overlaps the electronic component 3112 when viewed in the normal direction of the main surface 201. The conductive chip component 42H is connected and fixed to the grounding terminal of the electronic component 3112 by a conductive adhesive 400. The conductive chip component 42H is connected to the conductive film 60 formed in the concave portion 51 of the sealing resin 50.

In such a configuration, similarly to the electronic component module 10, the electronic component module 10H can realize high-density mounting and high shielding properties. Further, in this configuration, even if the grounding terminals of the plurality of electronic components are not adjacent to each other, the shielding property by the conductive chip component can be realized.

### Tenth Embodiment

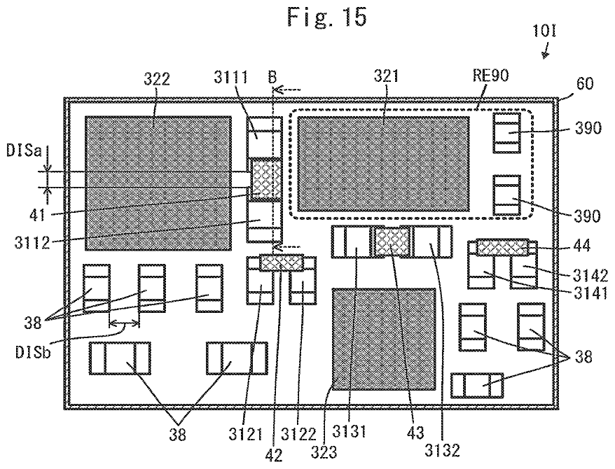

An electronic component module according to a tenth embodiment of the present disclosure will be described with reference to the drawings. FIG. 15 is a plan perspective view of an electronic component module according to the tenth embodiment. Note that FIG. 15 is a plan perspective view in a state where a top surface portion of the sealing resin and the shield film is seen through.

As illustrated in FIG. 15, an electronic component module 10I according to the tenth embodiment is different from the electronic component module 10 according to the first embodiment in that a distance between electronic components is defined. Other specific configurations of the electronic component module 10I are similar to those of the electronic component module 10, and description of the similar parts will be omitted.

In the electronic component module 10I, a distance between the electronic component 3111 and the electronic component 3112, a distance between the electronic component 3121 and the electronic component 3122, a distance between the electronic component 3131 and the electronic component 3132, and a distance between the electronic component 3141 and the electronic component 3142 are shorter than distances between adjacent electronic components 38 in the plurality of electronic components 38.

For example, a maximum distance DISa in the distance between the electronic component 3111 and the electronic component 3112, the distance between the electronic component 3121 and the electronic component 3122, the distance between the electronic component 3131 and the electronic component 3132, and the distance between the electronic component 3141 and the electronic component 3142 is smaller than a minimum distance DISb of the adjacent electronic component 38.

In other words, the distance between the electronic components on which the conductive chip component is disposed is smaller than the distance between the electronic components on which the conductive chip component is not disposed. Note that the distance between the electronic components in the specific functional circuit RE 90 may be equal to or shorter, or equal to or longer than the distance between the electronic components in which the conductive chip components are disposed.

Further, in other words, the distance between the electronic components disposed between the electronic component 321 and the electronic component 322, which are electronic components to be shielded, and the distance between the electronic components disposed between the electronic component 321 and the electronic component 323, which are electronic components to be shielded, are smaller than the distance between adjacent electronic components in other regions (positions different from the positions between the electronic components to be shielded).

With such a configuration, the electronic component module 10I can more effectively suppress electromagnetic field coupling between the electronic component 321 and the electronic component 322 and electromagnetic field coupling between the electronic component 321 and the electronic component 323. In addition, in the configuration of FIG. 15, the electronic component module 10I can more effectively suppress the electromagnetic field coupling between the electronic component 322 and the electronic component 323.

Note that the configurations of the above-described embodiments can be appropriately combined, and operations and effects according to the respective combinations can be exhibited.

10, 10A, 10B, 10C, 10D, 10E, 10F, 10G, 10H, 10I electronic component module

20 substrate

21, 22 land electrode

23 terminal electrode

24 conductor pattern

38 electronic component

41, 41A, 41C, 41H, 42, 42H, 43, 43C, 44 conductive chip component

50 sealing resin

51 concave portion

60 conductive film

201, 202 main surface

203 side surface

321, 322, 323, 331, 332, 390 electronic component

400 conductive adhesive

409 adhesive

411, 411G, 412, 431, 432 conductive chip component

501 top surface

502 side surface

3111, 3112, 3113, 3114, 3115, 3121, 3122, 3131, 3132, 3133, 3141, 3142 electronic component

C411 insulating film

1. An electronic component module comprising:
a substrate having a main surface;
a plurality of electronic components including a first electronic component and mounted on the main surface of the substrate, the first electronic component including a grounding terminal at a side end portion;
an insulating sealing resin covering the plurality of electronic components and the main surface of the substrate;
a conductive film covering an outer surface of the sealing resin; and
a conductive chip component disposed on a side opposite to the substrate in the first electronic component in a normal direction of the main surface and connected to a grounding terminal of the first electronic component, wherein
the conductive film is connected to the conductive chip component,
the sealing resin includes a concave portion in a portion overlapping the conductive chip component as viewed in the normal direction of the main surface,
the conductive film has a portion provided in the concave portion,
the conductive chip component is disposed between the portion provided in the concave portion and the first electronic component, and
the portion of the conductive film provided in the concave portion is connected to the conductive chip component.

2. The electronic component module according to claim 1, wherein
the plurality of electronic components includes a second electronic component,
the second electronic component includes a grounding terminal at a side end portion, and
the conductive chip component is disposed on a side opposite to the substrate in the first electronic component and the second electronic component in the normal direction of the main surface, and connected to the grounding terminal of the first electronic component and the grounding terminal of the second electronic component.

3. The electronic component module according to claim 2, wherein the first electronic component and the second electronic component are disposed adjacent to each other.

4. The electronic component module according to claim 2, wherein
the first electronic component is lower in height than the second electronic component, and
the conductive chip component includes a portion overlapping the first electronic component thinner than a portion overlapping the second electronic component as viewed in the normal direction of the main surface.

5. The electronic component module according to claim 2, wherein
the plurality of electronic components includes a third electronic component,
the third electronic component is disposed between the first electronic component and the second electronic component, and
the conductive chip component and the third electronic component are spaced apart from each other.

6. The electronic component module according to claim 1, wherein
the plurality of electronic components includes a fourth electronic component,
the fourth electronic component includes a grounding terminal on a bottom surface, and
the conductive chip component is disposed on a side opposite to the substrate in the first electronic component and the fourth electronic component in the normal direction of the main surface, connected to the grounding terminal of the first electronic component, and in contact with a top surface of the fourth electronic component.

7. The electronic component module according to claim 6, further comprising
an insulating film disposed in a portion of the conductive chip component overlapping the fourth electronic component and covering the conductive chip component.

8. The electronic component module according to claim 7, wherein the first electronic component and the fourth electronic component are disposed adjacent to each other.

9. The electronic component module according to claim 6, wherein
the plurality of electronic components includes a fifth electronic component,
the fifth electronic component is disposed between the first electronic component and the fourth electronic component, and
the conductive chip component and the fifth electronic component are spaced apart from each other.

10. The electronic component module according to claim 1, wherein some of the plurality of electronic components overlapping the conductive chip component and the conductive chip component are disposed between at least one electronic component constituting a specific functional circuit of a high frequency module and other electronic components as viewed in the normal direction of the main surface.

11. The electronic component module according to claim 10, wherein some of the plurality of electronic components overlapping the conductive chip component and the conductive chip component is disposed so as to surround at least two sides of the at least one electronic component constituting the specific functional circuit as viewed in the normal direction of the main surface.

12. The electronic component module according to claim 10, wherein the specific functional circuit includes an amplifying element of a reception system of a high frequency signal.

13. The electronic component module according to claim 1, wherein
the plurality of electronic components comprises a plurality of shield target electronic components disposed so as to interpose the first electronic component and the conductive chip component as viewed in the normal direction of the main surface, wherein
a distance between some of the plurality of electronic components disposed between the plurality of shield target electronic components is shorter than a distance between others of the plurality of electronic components disposed at a position different from a position between the plurality of shield target electronic components.

14. The electronic component module according to claim 3, wherein
the first electronic component is lower in height than the second electronic component, and
the conductive chip component includes a portion overlapping the first electronic component thinner than a portion overlapping the second electronic component as viewed in the normal direction of the main surface.

15. The electronic component module according to claim 2, wherein
the plurality of electronic components includes a fourth electronic component,
the fourth electronic component includes a grounding terminal on a bottom surface, and
the conductive chip component is disposed on a side opposite to the substrate in the first electronic component and the fourth electronic component in the normal direction of the main surface, connected to the grounding terminal of the first electronic component, and in contact with a top surface of the fourth electronic component.

16. The electronic component module according to claim 3, wherein
the plurality of electronic components includes a fourth electronic component,
the fourth electronic component includes a grounding terminal on a bottom surface, and
the conductive chip component is disposed on a side opposite to the substrate in the first electronic component and the fourth electronic component in the normal direction of the main surface, connected to the grounding terminal of the first electronic component, and in contact with a top surface of the fourth electronic component.

17. The electronic component module according to claim 4, wherein
the plurality of electronic components includes a fourth electronic component,
the fourth electronic component includes a grounding terminal on a bottom surface, and
the conductive chip component is disposed on a side opposite to the substrate in the first electronic component and the fourth electronic component in the normal direction of the main surface, connected to the grounding terminal of the first electronic component, and in contact with a top surface of the fourth electronic component.

18. The electronic component module according to claim 7, wherein
the plurality of electronic components includes a fifth electronic component,
the fifth electronic component is disposed between the first electronic component and the fourth electronic component, and
the conductive chip component and the fifth electronic component are spaced apart from each other.

19. The electronic component module according to claim 2, wherein some of the plurality of electronic components overlapping the conductive chip component and the conductive chip component are disposed between at least one electronic component constituting a specific functional circuit of a high frequency module and other electronic components as viewed in the normal direction of the main surface.

20. The electronic component module according to claim 3, wherein some of the plurality of electronic components overlapping the conductive chip component and the conductive chip component are disposed between at least one electronic component constituting a specific functional circuit of a high frequency module and other electronic components as viewed in the normal direction of the main surface.
